(19) United States
(12) Patent Application Publication
(10) Pub. No.: US 2008/0032454 A1
(43) Pub. Date: Feb. 7, 2008

(54) Thermally Enhanced BGA Package Substrate Structure and Methods

(76) Inventors: Matthew Romig, Richardson, TX (US); Jovanie Dolorico Claver, Merrillville, IN (US)

Correspondence Address: TEXAS INSTRUMENTS INCORPORATED, P O BOX 655474, M/S 3999, DALLAS, TX, 75265, US

(21) Appl. No.: 11/462,736

(22) Filed: Aug. 7, 2006

(51) Int. Cl. H01L 21/58

(52) U.S. Cl. 438/122; 438/125; 438/667; 438/612

(57) ABSTRACT

Methods for preparing thermally enhanced multilayer substrates and methods for their use in assembling BGA packages are disclosed. Steps in preferred embodiments of the invention include opening a hole in a dielectric material at one surface of a multilayer substrate thereby forming a die pad on the second metal layer or primary thermal spreading layer. A plurality of vias are provided through the substrate from the surface of the die pad to the opposing surface of the substrate. In an alternative embodiments of the invention, an embedded thermal conductor is also formed on the die pad. In another embodiment, a hole in an bottom dielectric layer exposing a bottom metal layer and embedded thermal conductor may also be provided between the bottom of the substrate and the second metal layer from the bottom, e.g. the third and fourth layers. The die pad may be plated, cleaned, and/or masked to receive a die. The thermally improved substrates may be used for assembling BGA packages by introducing them into known package production processes.

### TECHNICAL FIELD

The invention relates to electronic semiconductor devices and manufacturing. More particularly, the invention relates to surface-mount BGA-packaged semiconductor devices and to methods for the manufacture of the same, providing thermal enhancement which may be used with standard assembly processes.

### BACKGROUND OF THE INVENTION

The ball grid array (BGA) is a well-known type of surface-mount package that utilizes an array of metallic nodules, often denominated “solder balls” although they are not necessarily spherical, as means for providing external electrical connections. The solder balls are attached to a layered substrate at the bottom side of the package. The die, or integrated circuit (IC) chip of the BGA is connected to the substrate commonly either by wirebond or flip-chip connections. The layered substrate of a BGA has internal conductive paths that electrically connect the chip bonds to the ball array. This substrate is typically encapsulated with a plastic mold or glob top to form the top of the package. Typically a BGA, or PBGA (plastic ball grid array), a type of BGA that uses a plastic or organic material for the substrate construction, is mounted onto a printed circuit board (PCB) and used in applications requiring high reliability. For convenience, the term BGA is used herein to refer to both BGAs and PBGAs unless noted otherwise. In conventional surface-mount type BGA, a semiconductor chip is mounted on a substrate with an adhesive material. Bond wires couple contact pads on the chip with contact pads incorporated into the surface of the substrate. An encapsulant material forms a protective covering over the chip, bond wires, and some or all of the substrate. Solder balls are attached at predetermined contact points, such as ball attachment holes on the bottom surface of the substrate disposed in an array for mounting on a printed circuit board (PCB).

An advantage of the BGA or PBGA for integrated circuit (IC) packaging is its high interconnection density, i.e., the number of balls per given package volume is high. All packages have drawbacks, however, and the BGA is no exception. The high density of the BGA which makes it desirable for many applications can lead to a concentration of excess heat generated during operation of the circuitry. In general, the semiconductor chip in the packaged device generates heat when operated and cools when inactive. Due to the changes in temperature, the BGA package as a whole tends to thermally expand and contract. However, since in many cases the thermal expansion behavior of the package, its internal components, e.g., chip, substrate, and PCB differ, stresses can occur at the connecting solder balls, or within the layers of the PCB, or among the components of the package.

In general, the excess heat making its departure from a BGA package common in the arts may be understood in terms of following three thermal paths. Heat may travel from the chip through the top of the package. This is typically a relatively poor heat path due to inherent heat resistance of the encapsulant material, although heat conduction may sometimes be improved by the use of heat-conductive mold compound material, the inclusion of a heat spreader or external thermal conductor, or by using a thin mold cap. Another thermal path is in the plane of the substrate. This can be a better heat path than through the encapsulant, particularly in packages with multilayer substrates, as it allows the substrate to more effectively spread heat out before it gets to the PCB. Typically the inner layers of the substrate, e.g., the second and third layers, are thicker than the outer layers, e.g., the first and fourth layers, and so may be more thermally advantageous. Additionally, the second layer is typically connected to the ground potential, making it the most continuous layer, as opposed to other layers, which are typically connected with isolated signals or power supplies, which are not as thermally advantageous. Thus, what may be termed a “primary thermal spreading plane”, often the second layer, is usually the most significant thermal path for BGA packages. Still another, more direct thermal path exists to the PCB, from the chip through the substrate. This path is sometimes improved by the addition of thermal vias or thermal BGA balls designed to increase heat conduction through the chip and substrate and into the PCB respectively. These improvements are necessarily limited by the available area and are not sufficient in all cases however, leaving a need for thermally enhanced BGA packages.

To further address the problem of dissipating excess heat, BGA-packaged semiconductor devices are known in the arts which are characterized by a heat spreader interposed between the semiconductor chip and the PCB. The heat spreader is designed to conduct heat away from the semiconductor chip in order to reduce thermally induced stress and increase package and IC reliability. The heat spreader is typically made from copper or other metal or ceramic material selected for its heat conductive properties. This technology, however, has its own problems. One problem is related to assembly of the package onto the PCB. Manufacturing and interposing the heat spreader between the semiconductor chip and the PCB complicates production procedures, resulting in increased costs. Also, there are various challenges to attaching the heat spreader to the substrate, and in sealing the junctions between the heat spreader, chip, and substrate. Also, due to rigid attachment of the heat spreader to the PCB, there may be a degradation in reliability of the device due to the effects of thermally-induced stresses. Additionally, although it is desirable to make the heat spreader large in order to dissipate heat more effectively, larger sizes can lead to further problems such as increased susceptibility to warpage or decreased reliability under stress.

Thermal enhancements known in the arts for BGA packages are faced with the additional problem of increasing the cost of the overall package. In general, to the extent the standard assembly process is disrupted, efficiency and yield decrease and costs increase. Due to these and other problems, it would be useful and advantageous to provide surface-mountable semiconductor packages, such as for example BGA and PBGA packages, with improved thermal conduction properties, and to provide methods for manufacturing and using the same within the context of established production processes.

### SUMMARY OF THE INVENTION

In carrying out the principles of the present invention in accordance with preferred embodiments thereof, using methods compatible with established manufacturing processes, packaged BGA devices are provided with improved thermal paths for removing excess heat from the chip.

According to one aspect of the invention, a method for preparing a multilayer substrate for use in assembling a BGA package includes the step of opening a hole through one or more dielectric layers at one surface of the substrate to form a die pad directly on top of an inner metallic layer, often the second layer. In a further step, vias are formed through the substrate from the surface of the die pad to the opposing surface of the substrate. The exposed die pad surface is plated with metal and thereafter prepared for receiving a die.

According to another aspect of the invention, a method for assembling a BGA package includes steps for providing a thermally enhanced substrate having a plurality of alternating metallic and dielectric layers. The substrate includes an exposed copper die pad at one surface, prepared for receiving a die and underlain by vias terminating at the opposing surface of the substrate. According to further steps, a die is operably coupled to the die pad and solder balls are attached to the opposing side of the substrate, including above or adjacent to the via locations.

According to yet another aspect of the invention, a method for preparing a substrate having a plurality of alternating metallic and dielectric layers for use in assembling a BGA package includes a step for opening a hole through one or more dielectric layers on one surface of the substrate in order to form a die pad. In a further step, vias are formed through the substrate from the surface of the die pad to the opposing surface of the substrate. The exposed die pad surface is provided with an embedded thermal conductor and is thereafter prepared for receiving a die.

According to still another aspect of the invention, a method for assembling a BGA includes steps for providing a substrate having a plurality of alternating metallic and dielectric layers. The substrate also includes an exposed copper die pad at one surface. An embedded thermal conductor at the die pad is prepared for receiving a die and is underlain by vias terminating at the opposing surface. According to further steps, a die is operably coupled to the thermally enhanced die pad and solder balls are attached to the substrate surface at the via locations.

According to other aspects of preferred embodiments of the invention, thermally enhanced substrates are prepared for insertion into assembly processes using the invention.

The invention has advantages including but not limited to providing an improved thermal path for the egress of heat from a packaged semiconductor device and providing manufacturing methods compatible with, or readily adapted to, established assembly processes. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a cut-away side view of an example of a preferred embodiment of a substrate structure according to the invention;

FIG. 2A is a cut-away side view showing an early step in an example of a method of manufacturing substrate structures of FIGS. 1 and 3 according to preferred embodiments of the invention;

FIG. 2B is a cut-away side view showing a further step in the method of manufacturing substrate structures of FIGS. 1 and 3 according to preferred embodiments of the invention;

FIG. 2C is a cut-away side view showing an additional step in the method of manufacturing substrate structures of FIGS. 1 and 3 according to preferred embodiments of the invention;

FIG. 2D is a cut-away side view showing a step in the method of manufacturing substrate structures of FIGS. 1 and 3 according to preferred embodiments of the invention;

FIG. 2E is a cut-away side view showing a step in an example of a method of manufacturing a substrate structure of FIG. 1 according to a preferred embodiment of the invention;

FIG. 3 is a cut-away side view of an example of an alternative embodiment of a substrate structure according to the invention; and

FIG. 4 is a simplified process flow diagram showing steps in an example of preferred methods using a thermally enhanced substrate structure of the invention in a BGA package assembly process.

References in the detailed description correspond to like references in the various drawings unless otherwise noted. Descriptive and directional terms used in the written description such as top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DESCRIPTION OF PREFERRED EMBODIMENTS

In general, the invention enhances the thermal path in a semiconductor device package from the IC to the outer surface of the package. A thermally enhanced substrate structure is prepared for use with BGA semiconductor device assembly processes. In an approach common to alternative embodiments, thermal conductivity is enhanced between the IC and a primary thermal spreading plane within the substrate.

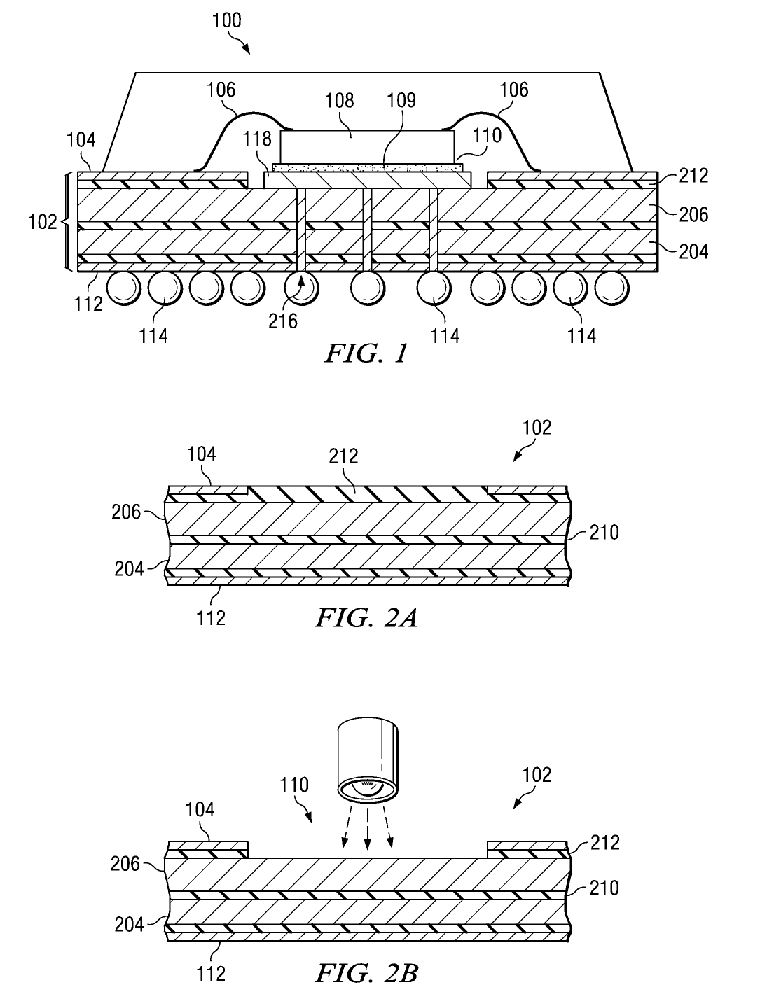

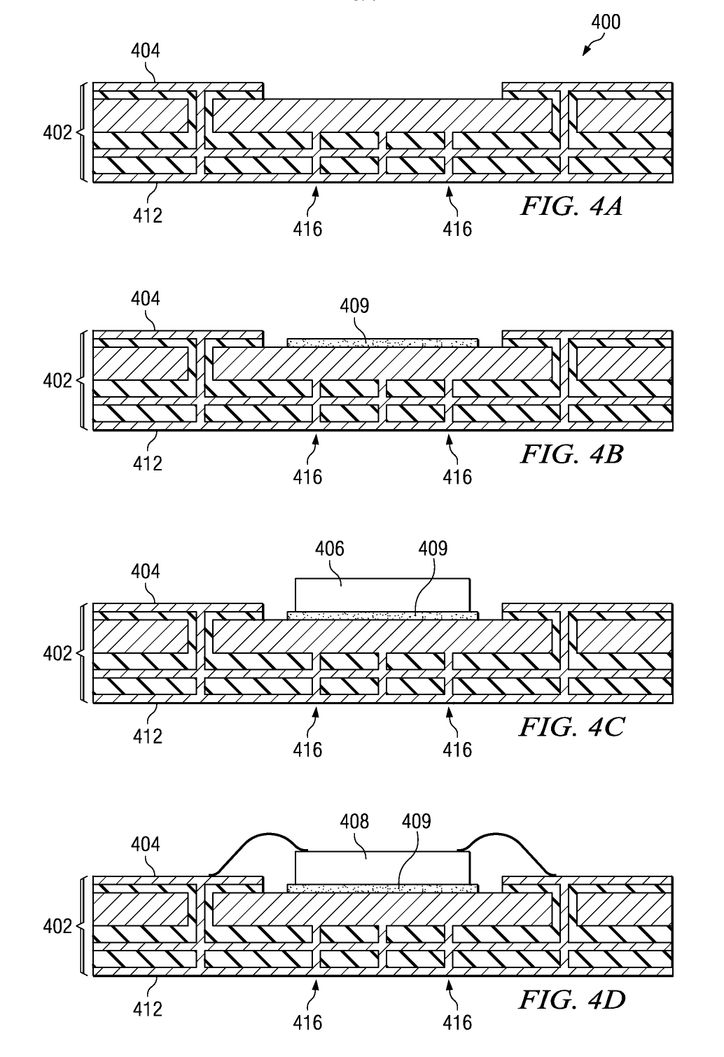

Now referring primarily to FIG. 1, an overview of an example of a preferred embodiment of a BGA package 100 according to the invention is shown in a cut-away side view. A multilayer substrate 102 provides the foundation of the package 100 as generally understood in the art. The substrate 102 carries interconnecting circuitry (not shown) and the top surface 104 of the substrate 102 accepts bond wires 106 as typically found in the art, completing electrical connections as dictated by the particular application for the operation of an integrated circuit (IC), or die 108 attached, usually using epoxy or other suitable adhesive 109, at a die pad 110. The opposing bottom surface 112 of the substrate 102 generally defines the outline or perimeter of the bottom of the package 100, typically provided with solder balls 114. The top surface 104, die 108, and bond wires 106 are preferably enclosed in encapsulant 116 for protection from the surrounding environment. According to one example of a preferred embodiment of the invention, an embedded thermal conductor 118, preferably copper, is provided at the die pad 110. The embedded thermal conductor 118 provides a solid thermally conductive mass to the die pad 110 made of metal or other material selected for its good thermal conductivity. In a further application of the invention an embedded thermal conductor may be included, alternatively or additionally, in alignment with the die pad area between additional layers of the package, e.g., between the bottom and next-to-bottom layers of FIG. 1 or FIG. 3.

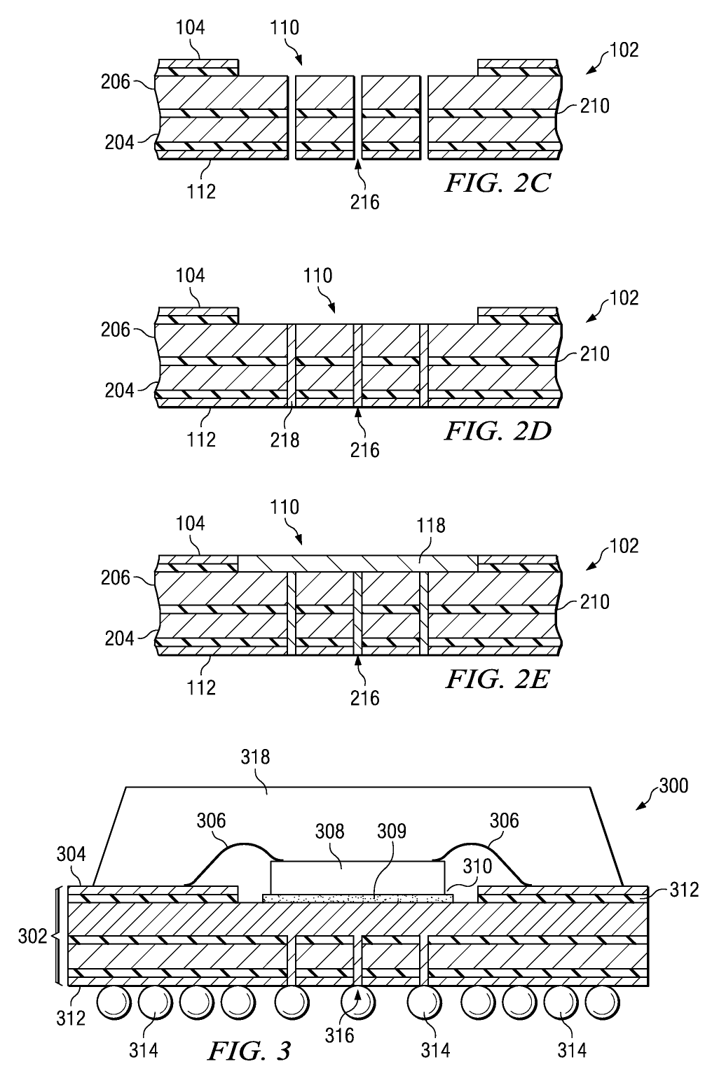

Now referring primarily to FIGS. 2A through 2E, a series of cut-away side views is used to illustrate the steps in examples of two alternative preferred methods of preparing thermally enhanced substrates within the practice of the invention. It should be apparent to those knowledgeable and skillful in the relevant arts that the description demonstrates the practice of the principles of the invention and is not necessarily exhaustive of all possible variations within the scope of the invention, although some alternative embodiments are also noted.

FIG. 2A is a cut-away side view showing an early step in a method of preparing a substrate for use in manufacturing a BGA package according to a preferred embodiment of the invention. A substrate 102 has multiple laminated layers, typically including at least a first metal layer 204 and a second metal layer 206, preferably both copper, with an interposing dielectric layer 210. A dielectric layer 212 is also present at the surface 104 of the substrate 102. Additional layers, not shown in the simplified drawings, may be present without altering the practice of the invention. As shown in FIG. 2B, a die pad portion 110 of the surface 104 of the substrate 102 is exposed. This could be achieved by a number of methods known in the arts such as patterning and etching, mechanically opening such as drilling, cutting, or punching, before or after lamination, or by laser drilling. The die pad 110 preferably is provided with vias 216 through to the opposing surface 112 of the substrate 102, as depicted in FIG. 2C. The die pad 110 is then preferably plated with copper 218, FIG. 2D. In the preferred embodiment of the invention, an embedded thermal conductor 118 may also be positioned on the die pad 110. The embedded thermal conductor 118 may be formed by deposition techniques, such as the application of a thick plating, sputtering, paste printing, or other chemical or electrochemical processes, or by placement of a discreet piece of metal, for example copper, as a pick-and-place part accompanied by suitable means of attachment, such as epoxy or solder, sufficient to embed the thermal conductor 118 in position at the die pad 110. The die pad 110 with the embedded thermal conductor 118 is preferably cleaned or solder masked in preparation for receiving a die, as shown at reference numeral 108, FIG. 1. The substrate structure 102 thus prepared is preferably introduced into a semiconductor package assembly process stream as known in the arts for inclusion in a thermally enhanced package, e.g. a BGA assembly 100 as shown in FIG. 1.

Again referring primarily to FIG. 1, it can be seen that the thermally enhanced substrate 102 incorporated into the package 100 shown has a second metallic layer 206, in this example copper, adapted to receive an embedded thermal conductor 118 in a die pad 110. It should be apparent to those familiar with the arts that this second metallic layer 206 should be designed for improved heat flow in all directions, including increased layer thickness and layout based on heat flow paths. It should also be apparent to those familiar with the arts that the thermal vias 216 may be designed and built so as to provide enhanced heat transfer from the second substrate layer 206 to the solder balls 114, including increased amounts of metal or thermally conducting material, and layout to allow many thermal vias 216 as possible. The substrate 102 preferably has solder ball attachment points or pads patterned for receiving solder balls 114. The attachment of the solder balls 114 includes solder balls 114 positioned at the terminal ends of the vias 216 in communication with the die pad 110. It should be appreciated by those skilled in the arts that these thermally enhancing features may be used within the context of established BGA and PBGA packaging processes using the thermally enhanced substrate 102. The elimination of a portion of the dielectric layer 212 ordinarily found obscuring the second metallic layer 206 of the substrate 102 improves the thermal path from the die pad 110 to the opposing surface 112 of the substrate 102 as well as the thermal path in the primary thermal spreading plane of the substrate 102. The embedded thermal conductor 118 further improves these thermal paths.

An alternative embodiment of the invention is shown in FIG. 3, in which a thermally enhanced substrate structure 302 is prepared in a manner analogous to that described herein with reference to FIGS. 2A though 2D, but without the steps illustrated in FIG. 2E. In this alternative embodiment, the substrate structure 302 is prepared with a die pad 310 directly on the outer metallic layer 306, preferably copper, without the addition of an embedded thermal conductor as shown and described with reference to FIG. 1 and FIG. 2E. A multilayer substrate 302 provides the foundation of the package 300 as above. The substrate 302 carries interconnecting circuitry (not shown) and the top surface 304 of the substrate 302 accepts bond wires 306 for the operable connection, using a suitable adhesive 309, of an IC die 308 to the die pad 310. The opposing bottom surface 312 of the substrate is preferably provided with solder balls 314. The top surface 304, die 308, and bond wires 306 are preferably enclosed in encapsulant 318. As noted with respect to the embodiment described above, the elimination of the portion of the dielectric layer 312 exposing the upper metallic layer 306 of the substrate 302 improves the thermal path from the die pad 310 to the opposing surface 312 of the substrate 302 as well as the thermal path in the plane of the substrate 302. Vias 316 preferably extend from the die pad 310 to the outer surface 312 of the substrate 302 to further enhance thermal conductivity away from the die pad 310 through the substrate 302. Preferably, the substrate thermally enhanced structure 302 shown and described in the package 300 of FIG. 3 may be used with established package assembly processes.

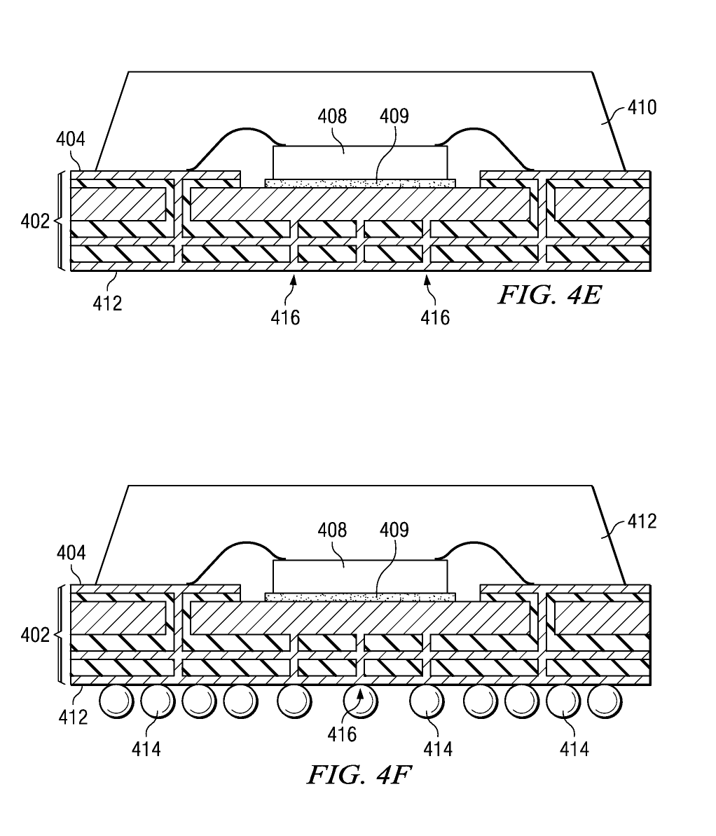

The methods of the invention may be implemented using cost-effective modifications to standard assembly processes. FIG. 4 is a simplified process flow diagram showing an alternative view of the steps in a preferred method 400 of assembling a BGA according to the invention. A thermally enhanced substrate is prepared 402, preferably according to the methods shown and described herein for producing the thermally enhanced substrate structures. As shown at step 404, a die pad is prepared for receiving a die, preferably either by cleaning the metallic surface of the die pad, or by preparing a solder mask to enhance adhesion. Now referring to steps 406 and 408 respectively, a semiconductor die is attached to the surface of the die pad, preferably using epoxy, and the wire bond connections are made to the appropriate locations on the substrate. The thermally enhanced substrate and die may then be encapsulated, step 410. Solder balls are preferably attached, 412, to the lower surface of the substrate, including to the vias in thermal communication between the lower surface of the substrate and the die pad.

The methods and apparatus of the invention provide one or more advantages including but not limited to improving heat dissipation using thermally enhanced substrate structures in packaged semiconductor devices adapted for use with known manufacturing processes. While the invention has been described with reference to certain illustrative embodiments, those described herein are not intended to be construed in a limiting sense. For example, variations or combinations of steps in the embodiments shown and described may be used in particular cases without departure from the invention, such as including an additional embedded thermal conductor between the “bottom” layers of the substrate (as shown in the drawings). Additionally, the enhanced substrate may also include solder mask patterning of the bottom surface to receive solder balls for enhancing heat flow out of the substrate. Modifications and combinations of the illustrative embodiments as well as other advantages and embodiments of the invention will be apparent to persons skilled in the arts upon reference to the drawings, description, and claims.

We claim:

1. A method for preparing a multilayer substrate for use in assembling a BGA package comprising the steps of:
on a substrate having a plurality of alternating metallic and dielectric layers, exposing a portion of a metallic layer at one surface of the substrate thereby forming a die pad;
forming a plurality of vias through the substrate from the surface of the die pad to the opposing surface of the substrate;
plating the exposed die pad surface with metal; and
preparing the plated die pad for receiving a die.

2. A method according to claim 1 wherein the step of preparing the plated die pad for receiving a die further comprises cleaning the metal surface of the die pad.

3. A method according to claim 1 wherein the step of preparing the plated die pad for receiving a die further comprises preparing a solder mask on the metal surface of the die pad.

4. A method according to claim 1 wherein the step of plating the die pad surface die further comprises applying copper.

5. A method for assembling a BGA package comprising the steps of:
providing a substrate having a plurality of alternating metallic and dielectric layers, the substrate further comprising an exposed portion of an upper metal layer forming a die pad, the die pad prepared for receiving a die and underlain by a plurality of vias terminating at the opposing surface of the substrate;
operably coupling a die to the die pad;
encapsulating the die; and
attaching solder balls to the substrate at the terminal ends of the vias.

6. A method according to claim 5 wherein the die pad comprises copper.

7. A method according to claim 5 further comprising the step of cleaning the metal surface of the die pad.

8. A method according to claim 5 further comprising the step of preparing a solder mask on the metal surface of the die pad.

9. A method for preparing a multilayer substrate for use in assembling a BGA package comprising the steps of:
on a substrate having a plurality of alternating metallic and dielectric layers, exposing a portion of a metallic layer at one surface of the substrate thereby forming a die pad;
forming a plurality of vias through the substrate from the surface of the die pad to the opposing surface of the substrate;
plating the exposed die pad surface with metal;
forming an embedded thermal conductor on the die pad; and
preparing the die pad for receiving a die.

10. A method according to claim 9 wherein the step of preparing the die pad for receiving a die further comprises cleaning the metal surface of the die pad.

11. A method according to claim 9 wherein the step of preparing the die pad for receiving a die further comprises preparing a solder mask on the metal surface of the die pad.

12. A method according to claim 9 wherein the step of plating the die pad surface die further comprises applying copper.

13. A method according to claim 9 wherein the step of forming the embedded thermal conductor on the die pad further comprises the deposition of metal on the surface of the die pad.

14. A method according to claim 9 wherein the step of forming the embedded thermal conductor on the die pad further comprises the mechanical placement of a thermal conductor on the die pad.

15. A method according to claim 9 wherein the embedded thermal conductor comprises copper.

16. A method according to claim 9 wherein the embedded thermal conductor comprises silicon.

17. A method according to claim 9 wherein the embedded thermal conductor comprises solder.

18. A method according to claim 9 wherein the embedded thermal conductor comprises a ceramic material.

19. A method according to claim 9 further comprising the step of forming one or more additional embedded thermal conductors in the substrate in alignment with the die pad.

20. A method for assembling a BGA package comprising the steps of:
providing a substrate having a plurality of alternating metallic and dielectric layers, the substrate further comprising a die pad portion of an upper metal layer exposed at one surface, the die pad having an embedded thermal conductor, and prepared for receiving a die, the embedded thermal conductor underlain by a plurality of vias terminating at the opposing surface of the substrate;
operably coupling a die to the die pad;
encapsulating the die; and
attaching solder balls to substrate at the terminal ends of the vias.

21. A method according to claim 20 further comprising the step of forming one or more additional embedded thermal conductors in the substrate in alignment with the die pad.

22. A method according to claim 20 wherein the one or more embedded thermal conductor comprises copper.

23. A method according to claim 20 wherein the one or more embedded thermal conductor comprises silicon.

24. A method according to claim 20 wherein the one or more embedded thermal conductor comprises solder.

25. A method according to claim 20 wherein the one or more embedded thermal conductor comprises a ceramic material.
